(19) United States
(12) Patent Application Publication
(10) Pub. No.: US 2026/0191038 A1
(43) Pub. Date: Jul. 2, 2026

(54) SEMICONDUCTOR DEVICE

(71) Applicant: NANYA TECHNOLOGY CORPORATION, New Taipei City (TW)

(72) Inventor: Hsu Chiang, New Taipei City (TW)

(73) Assignee: NANYA TECHNOLOGY CORPORATION, New Taipei City (TW)

(21) Appl. No.: 19/004,420

(22) Filed: Dec. 29, 2024

(51) Int. Cl. H01L 23/00; H01L 23/31; H01L 23/538; H10B 80/00

(52) U.S. Cl. CPC H10W 70/611; H10B 80/00; H10W 70/635; H10W 74/141; H10W 90/794

(57) ABSTRACT

A semiconductor device includes an interposer and a plurality of memory dies. The interposer has a first surface and a second surface opposite to the first surface. The interposer includes first bonding pads adjacent to the first surface. The plurality of memory dies are arranged in an array on the first surface of the interposer. Each of the plurality of memory dies includes second bonding pads, and the second bonding pads are in direct contact with the corresponding first bonding pads.

### BACKGROUND

### Technical Field

The present invention relates to a semiconductor device, and in particular to a memory device.

Description of Related Art

With the development of the industry, the demand for a greater memory capacity increases. A 3-dimensional (3D) memory stack stacked in a direction vertical to a surface of the substrate is developed to increase the capacity. However, the 3D memory stack has limited input/outputs (I/Os), which may limit the transmission speed of signals.

### SUMMARY

The present invention provides a semiconductor device, which has increased number of I/O.

The semiconductor device of the present invention includes an interposer and a plurality of memory dies. The interposer has a first surface and a second surface opposite to the first surface. The interposer includes first bonding pads adjacent to the first surface. The plurality of memory dies are arranged in an array on the first surface of the interposer. Each of the plurality of memory dies includes second bonding pads, and the second bonding pads are in direct contact with the corresponding first bonding pads.

In an embodiment of the semiconductor device of the present invention, the second bonding pads are bonded with the corresponding first bonding pads to form conductive bonding structures.

In an embodiment of the semiconductor device of the present invention, the semiconductor device further includes an encapsulant disposed on the interposer and laterally encapsulating the plurality of memory dies.

In an embodiment of the semiconductor device of the present invention, the plurality of memory dies includes a first memory die and a second memory die arranged side by side. The encapsulant is located in a gap between the first memory die and the second memory die.

In an embodiment of the semiconductor device of the present invention, each of the plurality of memory dies has a first region and a second region surrounding the first region. Each of the plurality of memory dies further includes a substrate, a plurality of memory cells and logic circuits. The plurality of memory cells is located on the substrate in the first region. The logic circuits are located on the substrate in the second region. The plurality of memory cells are electrically connected with the interposer through the logic circuits.

In an embodiment of the semiconductor device of the present invention, the second bonding pads are located in the second region and electrically connected with the logic circuits.

In an embodiment of the semiconductor device of the present invention, the interposer further includes an interposer substrate, a redistribution structure and a plurality of through-substrate vias. The redistribution structure is disposed on the interposer substrate. The plurality of through-substrate vias penetrates through the interposer substrate and electrically connected with the redistribution structure.

In an embodiment of the semiconductor device of the present invention, the semiconductor device further includes a package substrate and a plurality of conductive connectors. The package substrate is disposed on the second surface of the interposer. The plurality of conductive connectors is disposed between the interposer and the package substrate.

In an embodiment of the semiconductor device of the present invention, the plurality of memory dies are electrically connected to the package substrate directly through the interposer and the plurality of conductive connectors.

In an embodiment of the semiconductor device of the present invention, the interposer further includes a first bonding dielectric layer adjacent to the first surface and the first bonding pads are located in the first bonding dielectric layer. Each of the plurality of memory dies further includes a second bonding dielectric layer facing the first bonding dielectric layer, the second bonding pads are located in the second bonding dielectric layer, and the first bonding dielectric layer is in direct contact with the second bonding dielectric layer.

Based on the above, the semiconductor device of the present application includes a plurality of memory dies arranged in an array on a same plane of the interposer. Therefore, the semiconductor device has high memory capacity and at the same time has increased number of input/output (I/O) and, and thereby improving the signal transmission speed.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic cross-sectional view of a semiconductor device according to an embodiment of the present invention.

FIG. 2 is a schematic top view of a semiconductor device according to an embodiment of the present invention.

FIG. 3 to FIG. 5 are schematic cross-sectional views of the manufacturing of a semiconductor device according to an embodiment of the present invention.

### DESCRIPTION OF THE EMBODIMENTS

The embodiments are described in detail below with reference to the accompanying drawings, but the embodiments are not intended to limit the scope of the present invention. In addition, the drawings are for illustrative purposes only and are not drawn to the original dimensions. For the sake of easy understanding, the same elements in the following description will be denoted by the same reference numerals.

In the text, the terms mentioned in the text, such as “comprising”, “including”, “containing” and “having” are all open-ended terms, i.e., meaning “including but not limited to”.

When using terms such as “first” and “second” to describe elements, it is only used to distinguish the elements from each other, and does not limit the order or importance of the devices. Therefore, in some cases, the first element may also be called the second element, the second element may also be called the first element, and this is not beyond the scope of the present invention.

In addition, the directional terms, such as “on”, “above”, “under” and “below” mentioned in the text are only used to refer to the direction of the drawings, and are not used to limit the present invention.

Also, herein, a range expressed by “one value to another value” is a general representation to avoid enumerating all values in the range in the specification. Thus, the recitation of a particular numerical range encompasses any numerical value within that numerical range, as well as smaller numerical ranges bounded by any numerical value within that numerical range.

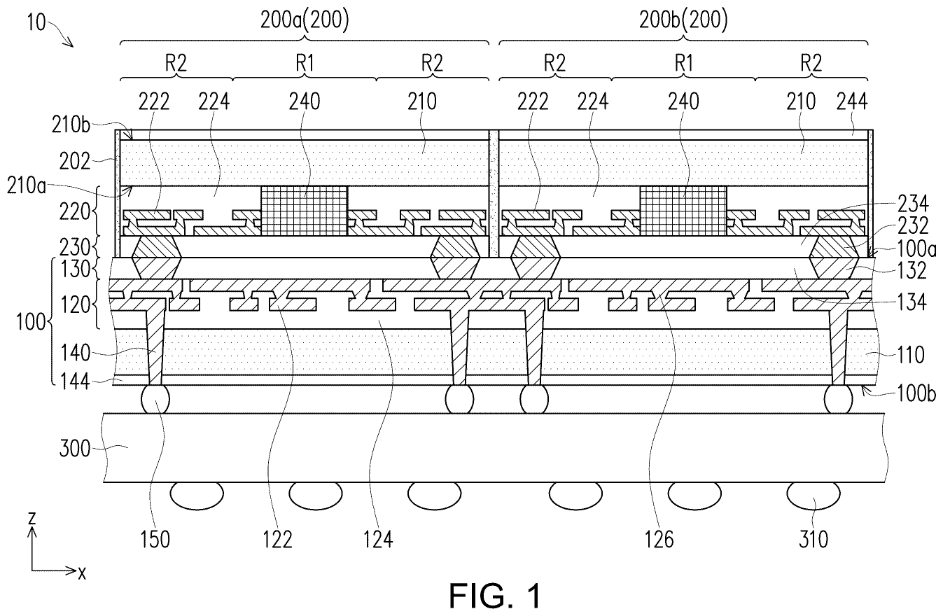

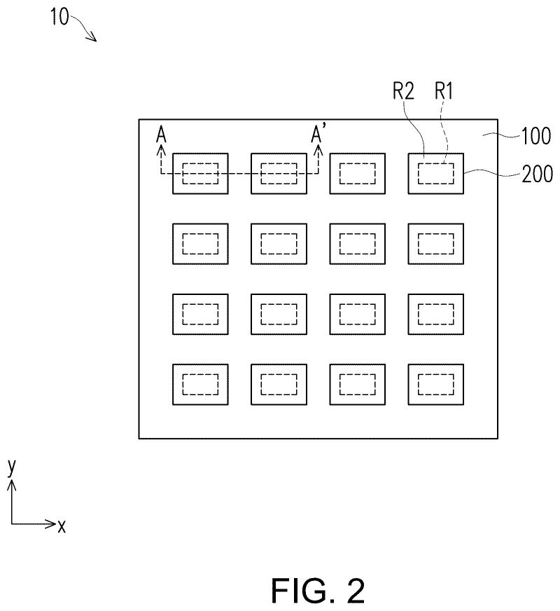

FIG. 1 is a schematic cross-sectional view of a semiconductor device according to an embodiment of the present invention. FIG. 2 is a schematic top view of a semiconductor device according to an embodiment of the present invention. FIG. 1 may be a cross-sectional view taken along a line A-A′ shown in FIG. 2. For clarity, FIG. 2 only shows an interposer 100 and memory dies 200, and other components are omitted.

Referring to FIG. 1 and FIG. 2, the semiconductor device 10 includes an interposer 100 and a plurality of memory dies 200. The interposer 100 has a first surface 100a and a second surface 100b opposite to the first surface 100a. The plurality of memory dies 200 (including a first memory die 200a and a second memory die 200b) are arranged in an array on the first surface 100a of the interposer 100. In some embodiments, the semiconductor device 10 further includes a package substrate 300 disposed on the second surface 100b of the interposer 100.

In some embodiments, the interposer 100 includes an interposer substrate 110, a redistribution structure 120, a first bonding layer 130 and through-substrate vias 140. The redistribution structure 120 is disposed on the interposer substrate 110 and the first bonding layer 130 is disposed on the redistribution structure 120. The through-substrate vias 140 penetrate through the interposer substrate 110 and electrically connected with the redistribution structure 120.

In some embodiments, the interposer substrate 110 is a semiconductor substrate. A material of the interposer substrate 110 includes silicon, germanium or other suitable semiconductor materials. In some embodiments, the interposer substrate 110 is a silicon wafer.

In some embodiments, the redistribution structure 120 includes conductive layers 122 and dielectric layers 124 stacked alternatively on the interposer substrate 110. In some embodiments, the redistribution structure 120 further includes conductive vias 126 electrically connected between the adjacent conductive layers 122 in a z direction. In some embodiments, materials of the conductive layers 122 and the conductive vias 126 include copper, titanium, a combination thereof, an alloy thereof or other suitable conductive materials. In some embodiments, a material of the dielectric layers 124 includes silicon oxide or other suitable dielectric materials.

In some embodiments, the first bonding layer 130 includes a first bonding dielectric layer 134 and first bonding pads 132 located in the first bonding dielectric layer 134. The first bonding pads 132 are electrically connected to the conductive layer 122 of the redistribution structure 120. In some embodiments, a material of first bonding pads 132 includes copper, titanium, a combination thereof, an alloy thereof or other suitable conductive materials. In some embodiments, a material of the first bonding dielectric layer 134 is the same as the material of the dielectric layer 124, for example, the material of the first bonding dielectric layer 134 includes silicon oxide. However, the present invention is not limited thereto. In other embodiments, the material of the first bonding dielectric layer 134 is different from the material of the dielectric layer 124, for example, the material of the bonding dielectric layer 134 may include polyimide or other suitable dielectric materials.

In some embodiments, the first bonding pads 132 are tapered. That is, the first bonding pad 132 has a slant sidewall and a width measured along an upper surface of the first bonding pad 132 (that is, a surface of first bonding pad 132 close to the first surface 100a) is greater than a width measured along a lower surface of the first bonding pad 132 (that is, a surface of first bonding pad 132 the away from the first surface 100a).

In some embodiments, the through-substrate vias 140 also penetrate through a dielectric layer 124 and directly contact a conductive layer 122 to electrically connect with the conductive layer 122. In some embodiments, a material of through-substrate vias 140 includes copper, titanium, a combination thereof, an alloy thereof or other suitable conductive materials.

In some embodiments, a dielectric layer 144 is disposed on a side of the interposer substrate 110 opposite to the redistribution structure 120. In some embodiments, a material of the dielectric layer 144 is similar to that of the dielectric layers 124.

In some embodiments, the first bonding layer 130 is located close to the first surface 100a and the through-substrate vias 140 are located close to the second surface 100b. That is, the first bonding pads 132 are adjacent to the first surface 100a. In some embodiments, the first surface 100a is composed of surfaces of the first bonding pads 132 and the first bonding dielectric layer 134. In some embodiments, the second surface 100b is composed of a surface of the dielectric layer 144.

In some embodiments, the interposer substrate 110 may further include passive devices (such as capacitors, inductors, resistors or the like).

In some embodiments, as shown in FIG. 2, the plurality of memory dies 200 are arranged in a 4 rows×4 columns array along x direction and y direction, but it is not limited. The number of memory dies 200 is not limited and can be adjusted depending on the actual need. In other embodiments, the plurality of memory dies 200 may be arranged in a 2×2 array, a 6×6 array, a 8 x8 array, a 16×16 array or other suitable arrangements. Here, the x direction, y direction and z direction are perpendicular to each other.

In some embodiments, the plurality of memory dies 200 are located on the same layer and are not stacked vertically (that is, in z direction) with each other.

In some embodiments, the plurality of memory dies 200 includes a first memory die 200a and a second memory die 200b arranged side by side. Each of the plurality of memory dies 200 (including the first memory die 200a and the second memory die 200b) includes a substrate 210, an interconnect structure 220, a second bonding layer 230 and a plurality of memory cells 240. In some embodiments, each of the plurality of memory dies 200 has a first region R1 and a second region R2 surrounding the first region R1. The first region R1 may be a central region and the second region R2 may a peripheral region.

In some embodiments, the substrate 210 is a semiconductor substrate. A material of the substrate 210 includes silicon, germanium or other suitable semiconductor materials. In some embodiments, the substrate 210 has a front side 210a and a back side 210b. In some embodiments, a dielectric layer 244 is disposed on the back side 210b of the substrate 210.

In some embodiments, the plurality of memory cells 240 are disposed on the front side 210a of the substrate 210 in the first region R1. Each of the plurality of memory cells 240 may be a dynamic random access memory (DRAM) cell which includes one-transistor one-capacitor (1T1C) architecture. Please note the plurality of memory cells 240 are simplified to a box in FIG. 1 for clarity to indicate the relative location in the memory die 200 and the detail of the memory cells is not illustrated.

In some embodiments, the interconnect structure 220 is disposed on the front side 210a of the substrate 210 and electrically connected with the plurality of memory cells 240. In some embodiments, the interconnect structure includes conductive layers 222 and dielectric layers 224 alternatively stacked on the substrate 210. In some embodiments, the conductive layers 222 constitutes logic circuits of the memory die 200. The logic circuits are located in the second region R2 and extend into the first region R1 to electrically connect with the corresponding memory cells 240. In some embodiments, a material of the conductive layers 222 is similar to that of the conductive layers 122, and a material of the dielectric layers 224 and 244 are similar to that of the dielectric layers 124.

In some embodiments, the second bonding layer 230 includes a second bonding dielectric layer 234 and second bonding pads 232 located in the second bonding dielectric layer 234. The second bonding pads 232 are located in the second region R2 and are electrically connected to the logic circuits or the conductive layers 222 of the interconnect structure 220. In some embodiments, a material of the second bonding pads 232 is the same as that of the first bonding pads 132, and a material of the second bonding dielectric layer 234 is the same as that of the first bonding dielectric layer 134.

In some embodiments, the second bonding pads 232 are tapered. That is, the second bonding pad 232 has a slant sidewall and a width measured along an upper surface of the second bonding pad 232 (that is, a surface of the second bonding pad 232 close to the interconnect structure 220) is less than a width measured along a lower surface of the second bonding pad 232 (that is, a surface of the second bonding pad 232 away from the interconnect structure 220).

In some embodiments, the second bonding pads 232 are in direct contact with the corresponding first bonding pads 132 and the second bonding pads 132 are bonded with the corresponding first bonding pads 132 to form conductive bonding structures, so that the logic circuits of the memory dies 200 are electrically connected to the conductive layers 122 of the interposer 100. Therefore, the plurality of memory cells 240 in the memory die 200 is electrically connected with the interposer 100 through the logic circuits. Please note that in FIG. 1, an interface between the first bonding pads 132 and the second bonding pads 232 is clearly shown for ease of description, but in fact the interface between the first bonding pads 132 and the second bonding pads 232 is barely seen due to the fusion bonding between the first bonding pads 132 and the second bonding pads 232.

In some embodiments, the second bonding dielectric layer 234 is in direct contact with the first bonding dielectric layer 134 and second bonding dielectric layer 234 is bonded with the first bonding dielectric layer 134 to form insulative bonding structures. Please note that in FIG. 1, an interface between the first bonding dielectric layer 134 and the second bonding dielectric layer 234 is clearly shown for ease of description, but in fact the interface between the first bonding dielectric layer 134 and the second bonding dielectric layer 234 is barely seen due to the fusion bonding between the first bonding dielectric layer 134 and the second bonding dielectric layer 234.

In some embodiments, the semiconductor device 10 further includes an encapsulant 202 disposed on the interposer 100 and laterally encapsulating the plurality of memory dies 200. In some embodiments, the encapsulant 202 is located in a gap between the first memory die 200a and the second memory die 200b. In some embodiments, a material of the encapsulant 202 includes epoxy, molding compound or other suitable materials.

In some embodiments, the interposer 100 is electrically connected to the package substrate 300 through a plurality of conductive connectors 150. That is to say, the plurality of conductive connectors 150 is disposed between the interposer 100 and the package substrate 300. In some embodiments, the conductive connectors 150 include solder balls, metal bumps or other suitable conductive materials.

In some embodiments, each of the plurality of memory dies 200 are electrically connected to the package substrate 300 directly through the interposer 100 and conductive connectors 150, which means that the electrical signals of the memory dies 200 only pass through the interposer 100 and conductive connectors 150 to the package substrate 300, but do not pass through other chips or other components to the package substrate 300, and vice vera. In the present embodiment, there is no logic die disposed between the memory die 200 and the interposer 100.

In some embodiments, conductive terminals 310 are disposed on a surface of the package substrate 300 opposite to the interposer 100 to electrically connect the semiconductor device 10 to the outside component (such as printed circuit board or the like). In some embodiments, the conductive terminals 310 include solder balls, metal bumps or other suitable conductive materials.

In the present embodiment, the semiconductor device 10 includes the plurality of memory dies 200 arranged in an array along x direction and y direction on a same plane of the interposer 100. Therefore, compared with the semiconductor device including the plurality of memory dies stacked along the z direction, the semiconductor device 10 has increased number of input/output (I/O) and still remains high memory capacity. Since the number of I/O is increased, the signal transmission speed can be improved.

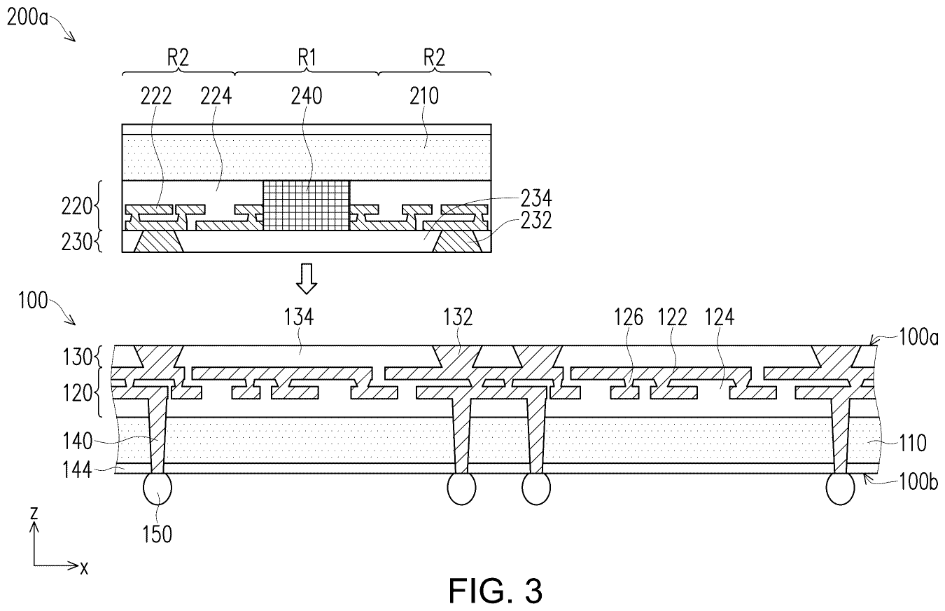

FIG. 3 to FIG. 5 are schematic cross-sectional views of the manufacturing of a semiconductor device according to an embodiment of the present invention. It must be noted here that the embodiment in FIG. 3 to FIG. 5 continues to use the referential numbers of the elements and a part of the contents of the embodiments of FIG. 1 and FIG. 2, wherein the same or similar referential numbers are used to denote the same or similar elements, and the description of the same technical contents is omitted. For the description of the omitted part, reference may be made to the foregoing embodiments, and details are not repeated here.

Referring to FIG. 3, an interposer 100 and a first memory die 200a are provided. The interposer 100 and the first memory die 200a are similar to the interposer 100 and the memory die 200 described in the previous embodiment.

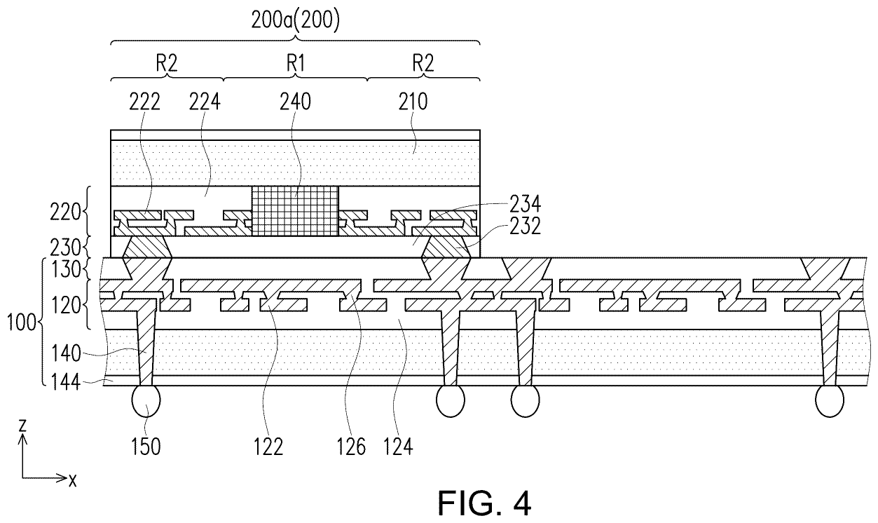

Referring to FIG. 4, the first memory die 200a is bonded to the interposer 100 by hybrid bonding. For example, the second bonding layer 230 of the first memory die 200a faces to the first bonding layer 130 of the interposer 100 and the second bonding pads 232 are aligned with the corresponding first bonding pads 132. Then, a metal-to-metal bonding is performed between the second bonding pads 232 and the first bonding pads 132, and a dielectric-to-dielectric bonding is performed between the second bonding dielectric layer 234 and the first bonding dielectric layer 134. Since the first memory die 200a is bonded to the interposer 100 by hybrid bonding, there is no micro-bumps or underfill sandwiched between the first memory die 200a and the interposer 100. The first memory die 200a is in direct contact with the interposer 100, so that the distance between the first memory die 200a and the interposer 100 can be minimized and thereby the signal transmission speed between the first memory die 200a and the interposer 100 may be improved. Besides, since there is no underfill formed between the first memory die 200a and the interposer 100, the heat dissipation for the first memory die 200a may be improved.

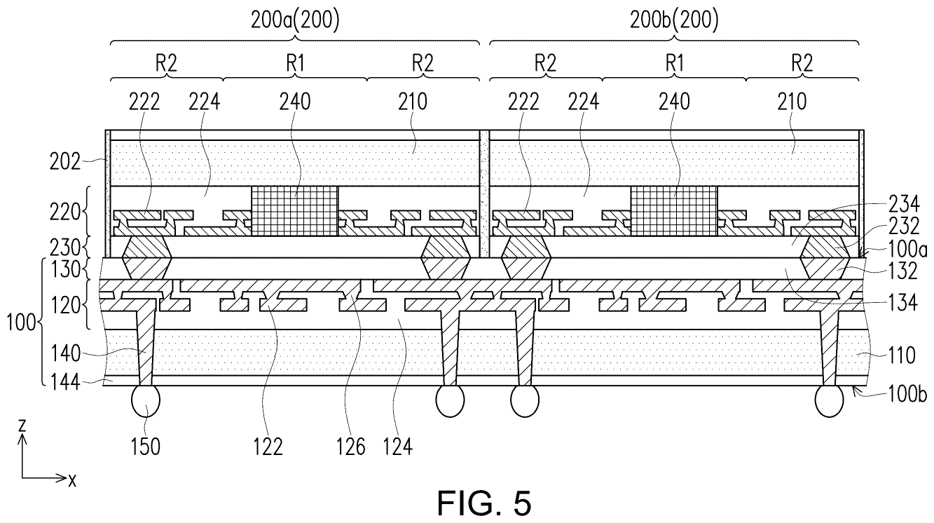

Referring to FIG. 5, similarly a second memory die 200b and more memory dies (not shown) are bonded to the interposer 100 by hybrid bonding. Then, an encapsulant 202 is formed on the interposer 100 by molding or other suitable methods to laterally encapsulate the memory dies 200.

In some embodiments, conductive connectors 150 are formed on the second surface 100b of the interposer 100 and electrically connected to the corresponding through-substrate vias 140. The conductive connectors 150 may be formed before or after the memory dies 200 are bonded to the interposer 100, which is not limited.

Referring back to FIG. 1, the structure shown in FIG. 5 is mounted on a package substrate 300. Conductive terminals are formed on the package structure 300 by screen printing or other suitable methods. Based on the above, the forming of the semiconductor device 10 is substantially completed.

Based on the above, the semiconductor device of the present application includes a plurality of memory dies arranged in an array on a same plane of the interposer. Therefore, the semiconductor device has high memory capacity and at the same time has increased number of input/output (I/O) and, and thereby improving the signal transmission speed.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A semiconductor device, comprising:
an interposer having a first surface and a second surface opposite to the first surface, wherein the interposer comprises first bonding pads adjacent to the first surface; and
a plurality of memory dies arranged in an array on the first surface of the interposer, wherein each of the plurality of memory dies comprises second bonding pads, and the second bonding pads are in direct contact with the corresponding first bonding pads.

2. The semiconductor device of claim 1, wherein the second bonding pads are bonded with the corresponding first bonding pads to form conductive bonding structures.

3. The semiconductor device of claim 1, further comprising:
an encapsulant disposed on the interposer and laterally encapsulating the plurality of memory dies.

4. The semiconductor device of claim 3, wherein the plurality of memory dies comprises a first memory die and a second memory die arranged side by side, wherein the encapsulant is located in a gap between the first memory die and the second memory die.

5. The semiconductor device of claim 1, wherein each of the plurality of memory dies has a first region and a second region surrounding the first region, and each of the plurality of memory dies further comprises:
a substrate;
a plurality of memory cells located on the substrate in the first region; and
logic circuits located on the substrate in the second region, wherein the plurality of memory cells are electrically connected with the interposer through the logic circuits.

6. The semiconductor device of claim 5, wherein the second bonding pads are located in the second region and electrically connected with the logic circuits.

7. The semiconductor device of claim 1, wherein the interposer further comprises:
an interposer substrate;
a redistribution structure disposed on the interposer substrate; and
a plurality of through-substrate vias penetrating through the interposer substrate and electrically connected with the redistribution structure.

8. The semiconductor device of claim 1, further comprising:
a package substrate disposed on the second surface of the interposer; and
a plurality of conductive connectors disposed between the interposer and the package substrate.

9. The semiconductor device of claim 8, wherein the plurality of memory dies are electrically connected to the package substrate directly through the interposer and the plurality of conductive connectors.

10. The semiconductor device of claim 1, wherein the interposer further comprises a first bonding dielectric layer adjacent to the first surface and the first bonding pads are located in the first bonding dielectric layer,
wherein each of the plurality of memory dies further comprises a second bonding dielectric layer facing the first bonding dielectric layer, the second bonding pads are located in the second bonding dielectric layer, and the first bonding dielectric layer is in direct contact with the second bonding dielectric layer.
